(19) United States
(12) Patent Application Publication
(10) Pub. No.: US 2014/0201434 A1
(43) Pub. Date: Jul. 17, 2014

(54) Managing Volatile File Copies

(71) Applicant: HEWLETT-PACKARD DEVELOPMENT COMPANY, L.P., (US)

(72) Inventors: Mujtaba Mohammed HASSANPUR, Union City, CA (US); Ivan Matias FONT, Sacramento, CA (US)

(73) Assignee: HEWLETT-PACKARD DEVELOPMENT COMPANY, L.P., Houston, TX (US)

(21) Appl. No.: 13/742,283

(22) Filed: Jan. 15, 2013

(51) Int. Cl. G11C 7/10; G06F 12/16

(52) U.S. Cl. CPC G11C 7/1072; G06F 12/16
USPC 711/104; 711/162

(57) ABSTRACT

Persistent files are copied from persistent memory to volatile memory to yield volatile files. At least some requests to open for writing or to close to writing persistent files are redirected to the corresponding volatile files. Openings to writing and closings to writing of volatile files are tracked to yield a synchronization record. Persistent files are synchronized to volatile files based on the synchronization record.

### BACKGROUND

Computer files are typically stored in persistent (i.e., non-volatile) memory so that they are not lost in the event of an intentional shutdown or an unintentional loss of power. These files typically contain data and instructions for manipulating the data. The manipulating typically involves reading and writing data from and to persistent memory. Various “caching” strategies provide for maintaining working copies of, e.g., recently used, data in volatile memory for faster access. Refinements involving caching data that has not been requested but that is predicted, e.g., based on proximity to requested data, to be requested can further improve effective access times.

### BRIEF DESCRIPTION OF THE DRAWINGS

The following figures represent examples and not the invention itself.

FIG. 1 is a schematic diagram of a file-management system in accordance with an example.

FIG. 2 is a flow chart of a file-management process implementable in the system of FIG. 1 in accordance with an example.

FIG. 3 is a schematic diagram of a computer system in accordance with an example.

FIG. 4 is a flow chart of a file-management process implementable in the computer system of FIG. 3 in accordance with an example.

### DETAILED DESCRIPTION

Most caching strategies have limited effectiveness where data is accessed randomly and used once (as opposed to repeatedly). For instance, management software for a large computer system (e.g., one that can support tens or hundreds of virtual machines, may maintain health data in separate files for each component of the system. Health analysis software may access the files in a hard-to-predict order and use the data once per access. In such a case, the original accesses from non-volatile memory will be relatively slow and accesses of cached data will be relatively rare. The result will be relatively slow overall performance.

In an example, an entire “persistent” file system in non-volatile memory is copied to volatile memory to yield a “volatile” file system. (Herein, “persistent” and “volatile”, as applied to file systems, file directories, and files, refer to the memory type in which the file systems, directories, and files are stored.) Subsequently, all file accesses can be from volatile memory for faster performance. A file manager can intercept messages calling for access to the original files in persistent memory and redirect them to access the corresponding copies on volatile memory. Changes to the volatile file system can be “written back” to the persistent file system to synchronize the persistent system with the volatile system.

Thus, for example, instead of caching a subset of the data represented in a file system in main memory, a working copy of the entire file system is transferred from persistent memory (e.g., a hard disk) to volatile memory (e.g., a random-access memory (RAM) disk). Once the transfer is complete, all accesses can be to volatile memory, even when a particular file or particular data within a file are being accessed for the first time (e.g., since a reboot). No effort is expended trying to predict which data is to be requested next. Accesses requested before the transfer is complete can be directed to the nonvolatile copy so there is negligible loss of performance during the transfer. Once the transfer is complete, performance is significantly enhanced relative to a system in which files are accessed from nonvolatile memory.

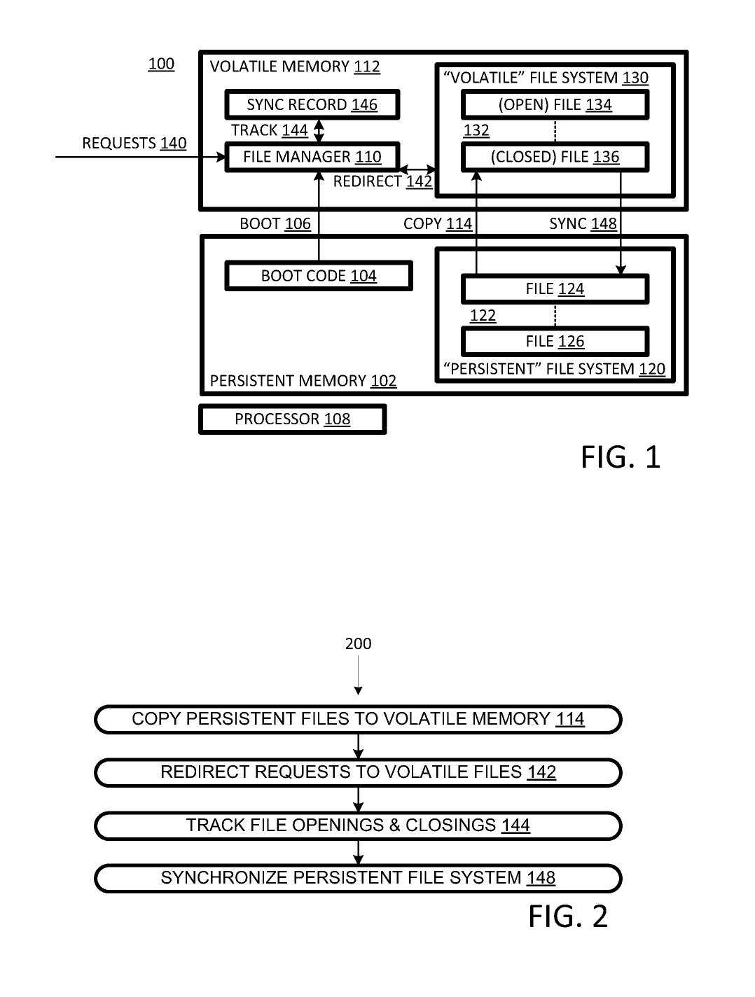

An example file management system 100, shown in FIG. 1, includes persistent memory 102 encoded with boot code 104. Boot code 104 is to, when executed (i.e., booted at 106) by a processor 108, create a file manager 110 executing in volatile memory 112. File manager 110 is to copy, at 114, persistent files 122 from a persistent file system 120 in persistent memory 102 to volatile memory 112 to yield volatile files 132 in a volatile file system 130 in volatile memory 112. For example, in the course of this copying, persistent file 124 of files 122 is copied from persistent memory 102 to volatile memory 112 to yield volatile file 134 of volatile files 132; likewise, volatile file 136 results from copying persistent file 126.

File manager 110 is further to handle file access requests 140, including requests to open files for writing and to close files to writing. File manager 110 is to redirect, at 142, requests intended for persistent file system 120 to volatile file system 130 so, for instance, a volatile file, e.g., file 134, is open, while another volatile file, e.g., file 136 is closed. File manager 110 is further to track, at 144, volatile file (open v. closed) status by updating a synchronization (sync) record 146 as volatile files are opened and closed. File manager 110 is further to synchronize, at 148 and based on sync record 146, volatile file system 130 to persistent file system 120 by writing back volatile files 132 to persistent file system 120.

A process 200, flow charted in FIG. 2, includes copying persistent files in persistent memory to volatile memory to yield volatile files at 114. At 142, file access requests intended for the persistent file system are redirected to the volatile file system. At 144, volatile file openings to provide write access and volatile file closings to end write access are tracked to yield a synchronization record. At 148, the persistent file system is synchronized with (i.e., modified as necessary to match) the volatile file system by writing back volatile files to the persistent file system. Note that system 100 can implement processes other than process 200, and that process 200 can be implemented by systems other than system 100.

Once copying is complete, the file manager can fulfill requests using the volatile file system instead of the persistent file system. Since files are accessed from relatively fast volatile memory instead of relatively slow persistent memory, the performance and responsiveness to requests of system 100 is enhanced relative to systems requiring access to files in persistent memory. As opposed to caching a subset of the file data in a cache, copying the entire file system to volatile memory avoids repeated interruptions due to cache misses and employs a simpler write-back strategy.

Different examples implement different policies for handling file access requests received during file copying. In a first example, no requests are fulfilled before copying is complete. In a second example, read-only requests received during file copying are fulfilled from persistent memory; write requests may be precluded or they may be fulfilled from persistent memory provided steps are taken to avoid losing the modifications during synchronization. In a third example, the file manager fulfills requests from volatile memory for files that have already been transferred (as indicated by the volatile file directory), and fulfills requests from persistent memory for files that have yet to be transferred to volatile memory.

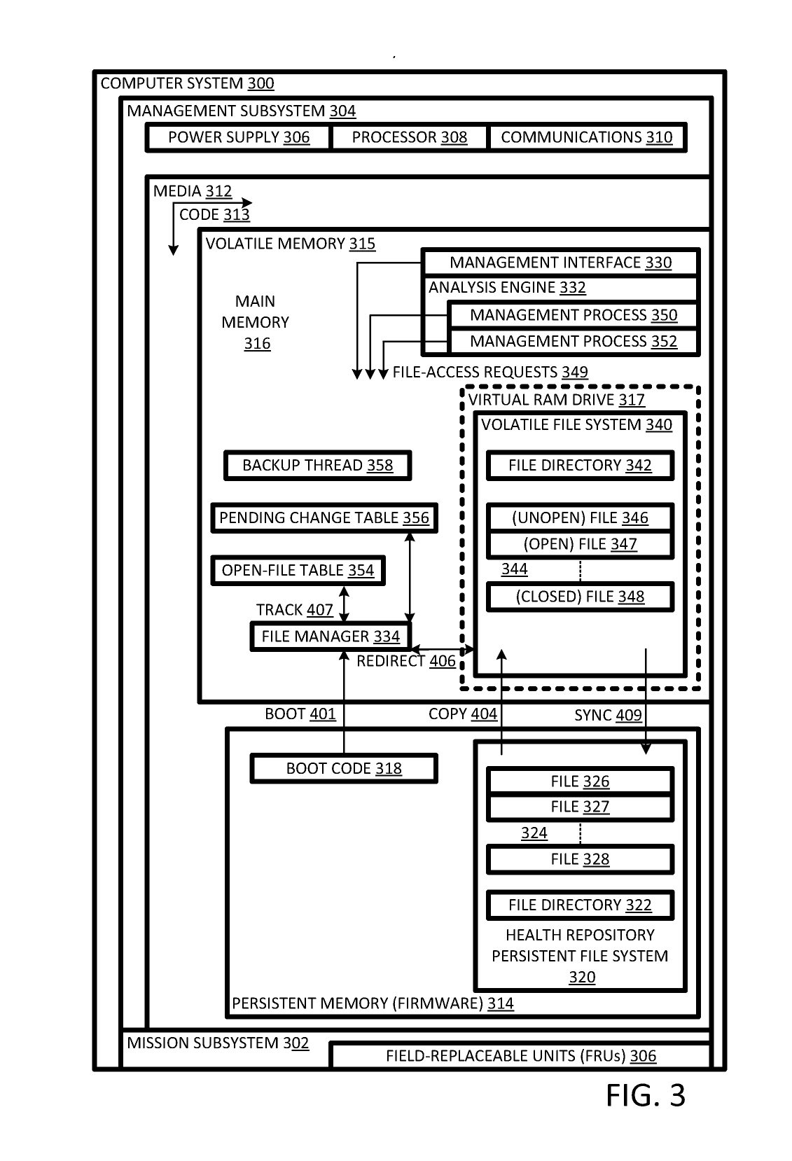

Computer system 300, shown in FIG. 3, has a scalable modular design suitable to mission-critical applications. Computer system 300 includes a mission subsystem 302 and a management subsystem 304. Mission subsystem 302 can come with, or be expanded to include, tens of blades, hundreds of processor cores, terabytes of random-access memory (RAM), and tens of multi-gigabit networking ports so that it can run tiers of critical applications on a common platform. Mission subsystem 302 is assembled using modular field-replaceable units (FRUs) 306, such as blades, blade subsystems, blade-chassis components (including fans and power supplies). Redundancy and fail-over mechanisms help ensure uninterrupted operation even in the face of failure of some components.

Management subsystem 304 is designed to further minimize interruptions generally and, especially, un-planned-for interruptions of mission-critical applications. Management subsystem 304 is a computer within a computer (e.g., within computer system 300) and includes its own power supply 306, processor 308, communications devices 310 (e.g., for communication with a remote management station over an out-of-band network), and non-transitory storage media 312. The storage media 312, which is encoded with code 313, includes persistent memory 314, and volatile memory 315, including main memory 316 and random-access memory configured as a virtual RAM drive 317.

Management subsystem 304 can be turned on and off independently of mission subsystem 302. Whether management subsystem 304 is on or off, its persistent memory 314 retains boot code 318 and a file system 320. File system 320 includes a file directory 322, and files 324, e.g., files 326, 327, and 328. The files, which, in practice, may number in the hundreds or thousands, contain data regarding mission subsystem 302 as a whole, respective FRUs 306, components of FRUs, and respective health-related events. For example, the files may include health analysis data (e.g., identifying a device and indicating whether or not it is operational) and error analysis data (identifying a device and also indicating a cause of a detected error).

When management subsystem 304 is turned on or restarted, boot code 318 is executed by processor 308 to establish in main memory 316 code defining the functionality of a management interface 330, an analysis engine 332, and a file manager 334, which serves as a database message handler for health database file system 320. Herein, the analysis engine is treated as a source of client processes for the file manager. In practice, the file manager can also be a process of the analysis engine. For example, an analysis engine can include, as components, a health repository system and a management interface. In this implementation, the health repository system can include a file manager for handling requests to a health repository database.

Management interface 330 cooperates with a network interface card (NIC) of communications devices 310 to allow a human or automated remote administrator access to persistent file system 320; for example, management interface 330 can provide a command-line or web-server interface to analysis engine 332, which, in turn, provides access to information in the health-repository files.

Analysis engine 332 is designed to automate and alleviate many of the tasks that otherwise would fall to a human administrator. Much of the data in health repository file system 320 is originally generated and stored by FRUs 306 of mission subsystem 302. As part of the boot process for management subsystem 304, analysis engine 332 collects the health data from the FRUs and from mission subsystem 302 generally for centralized storage in the health repository. Analysis engine 332 analyzes the collected information to detect existing and impending health problems, takes corrective action, and notifies a human administrator of any action that the human administrator may want to take.

Collecting health data from FRUs 306 for centralized storage in the health repository and analyzing the collected health data involves accessing a large number of files. If the accessing were of files in persistent memory, the time involved could be longer than desired, unacceptably extending boot time for management subsystem 304.

Health-repository file manager 334 helps limit management-subsystem boot times by copying files of persistent file system 320 from persistent memory 314 to virtual RAM drive 317 of volatile memory 315 so as to yield volatile file system 340. Volatile file system 340 includes a volatile file directory 342 and volatile files 344, including files 346, 347, and 348. Accessing files in a virtual RAM drive can take a fraction of the time required to access files in persistent memory. In an alternative example, a hardware RAM drive is used instead of a virtual RAM drive.

While volatile files 344 are created by copying persistent files 324, volatile file directory 342 is not created by copying persistent file directory 322. Instead, file manager 334 creates volatile file directory 342; volatile files are listed (e.g., by a local operating system) as they are created by copying. During an interval in which some files have been copied and others have yet to be copied, volatile file directory 342 lists only the files that have been copied to volatile file system 340.

In the example of FIG. 3, read-only file access requests 349 occurring before file copying is completed are fulfilled from persistent file system 320. In an alternative example, file access requests for a file representing a volatile memory file are fulfilled from volatile memory even if other files are yet to be copied from persistent memory to volatile memory.

Whenever a process, e.g., management process 350, is to write data, e.g., health-related data collected from FRUs 306 to a health-repository file, the file must be “open” for writing. While a file is open to a process for writing, it cannot be written to by any other process. Therefore, when a well-behaved process is finished writing to a file, it sends a close file message so that the previously opened file is then closed (and, thus, available to be opened for writing by another process).

File manager 334 keeps track of which volatile files are open and which volatile files that were previously open are closed. File manager 334, as it opens an existing or new volatile file for writing, lists the identity (file descriptor and name) of the volatile file in an open-file table 354. When the volatile file is subsequently closed for writing, its identity is deleted from open-file table 354 and entered into pending-change table 356.

Note that pending-change table 356 does not list “unopen” files, i.e., files that have not yet been open for writing. Thus, file manager 334 can distinguish at least four volatile file statuses: 1) “open” volatile files listed in open-file table 354; 2) “closed”, i.e., previously open but now closed, volatile files listed in pending-change table 356; 3) “unopened”, i.e., not-yet-opened files, listed in volatile file directory 342, but not in either open-file table 354 or pending-change table 356; and 4) uncopied persistent files, listed in persistent file directory 322 but not in volatile file directory 342. In an alternative example, the writing status of volatile files is indicated in the volatile file directory, which thus serves as a synchronization record; this alternative example omits the open-file table and the pending-change table.

If a volatile file listed in pending-change table 356 is reopened, e.g., at the behest of management process 352, for writing, its identity is not removed from the pending-change table 356. However, the identity is (re)entered into open-file table 354. Thus, some files can be represented in both open-file table 354 and pending-change table 356. If the file is closed again, it is deleted again from open-file table 354 and left in pending-change table 356. Each file appears at most once in the pending change table at any given time, regardless of the number of modifications to the file. Note, that if the file is deleted the second time it is opened, the pending-change record 356 can be updated to indicate that the corresponding persistent file is to be deleted rather than synchronized.

File manager 334 can create a backup thread 358 to indicate (e.g., periodic) times to synchronize persistent file system 320 to volatile file system 340 by writing volatile files listed in pending-change table 356 back to persistent file system 320. If pending-change table 356 indicates that a file is to be deleted, the corresponding file in persistent file system 320 is deleted without any writing back of a volatile file. Note that open-file table 354 and pending-change table 356 collectively serve as a synchronization record. In an example in which some file-access requests can be fulfilled from a volatile file system before file copying is complete, the volatile file directory, which indicates which files have been copied, is considered part of the synchronization record.

Synchronization can also be performed in response to a synchronization request, e.g., from client processes, or whenever pending-change table 356 is full. Also, a “suspend-synchronization” request can preclude synchronizations that otherwise would be triggered, e.g., by backup thread 358. In one scenario, a client planning to write a lot of data to one file or to the same set of files can improve performance by blocking synchronizations until the writing is complete. During synchronization, writes to pending-change table 356 are held off until synchronization is complete.

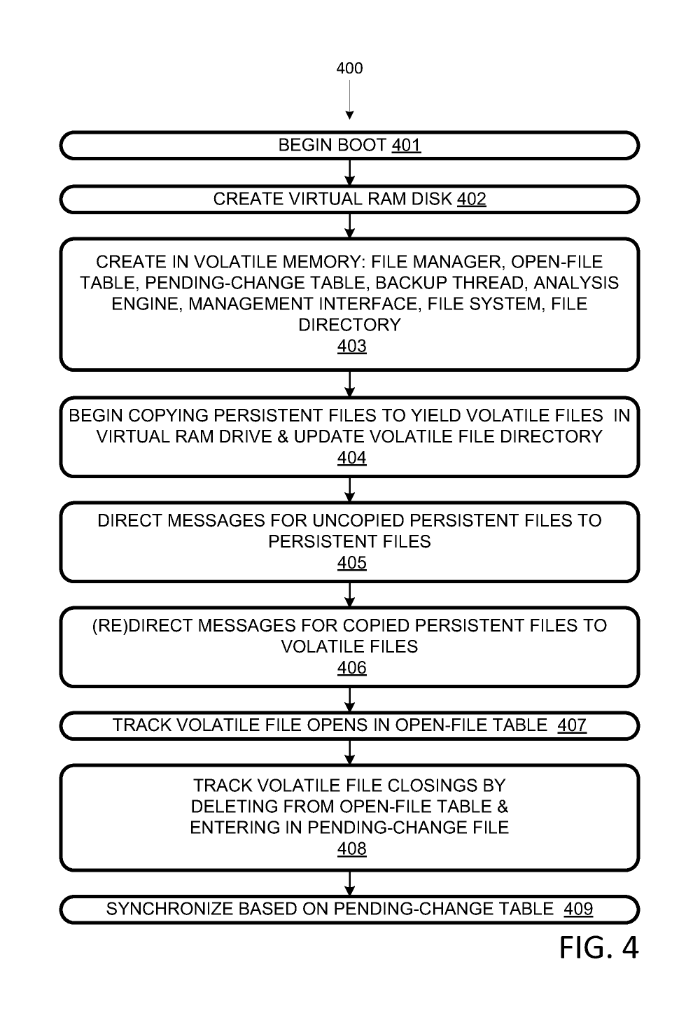

A process 400, implementable by system 300 and by other systems, is flow-charted in FIG. 4. At 401, booting begins, e.g., by powering on or resetting the management subsystem. At 402, a virtual RAM drive is created as part of the booting process. In an example, a hardware RAM drive exists apart from the booting process.

At 403, the file manager, the file system, the file directory, the open-file table, the pending-change table, the backup thread, the management interface, and the analysis engine result from booting. In system 300, booting launches the file manager (e.g., as part of the analysis engine and health-repository system). The file manager then creates several other entities, e.g., the file system and file directory in a virtual RAM drive and a backup thread in main memory. In another example, those other entities are not generated by the file manager.

At 404, the file manager begins copying persistent files to the virtual RAM drive to yield volatile files. The persistent file directory is not copied; instead, the volatile file directory lists volatile files as they are created in the copying process; typically an operating system updates file directories including the volatile file directory. In another example, the persistent file directory is copied to yield a volatile file directory.

At 405, while files are being copied, file-access requests (e.g., read-only file-access requests) may be fulfilled from persistent memory as discussed above. In an alternative example, received file-access requests are: 1) directed to the persistent version of a file if the file has not yet been copied to volatile memory (e.g., as indicated by the volatile file directory); and 2) redirected to the volatile version of a file if the file has been copied to volatile memory (e.g., so that it is represented in the volatile file directory). Depending on the variant, write-access requests made during file copying may be fulfilled or precluded. At 406, once file copying is complete, both read and write file-access requests are fulfilled from volatile memory.

At 407, when volatile files are opened for writing, their identities are added to the open-file table. At 408, when an open volatile file is closed to writing, its identity is removed from the open-file table and added to the pending-change table.

At 409, the persistent files are synchronized with the respective volatile files by writing back the volatile files to the persistent file system and overwriting prior persistent versions of the files. Synchronization can be triggered by a message. For example, a backup thread can notify the file manager to synchronize every 30 seconds. Also, synchronization can be triggered whenever the pending change table is full; as synchronized files are no longer pending-change files and can be removed from the pending-change list. Also, a periodic or other synchronization can be precluded in response to a suspend synchronization command, e.g., issued by a client process.

File manager 334 responds to the following request types. “Commit”: the file manager synchronizes, overwriting existing persistent files with their volatile counterparts. “Suspend Backup”: stops synchronization in response to triggers from the backup thread, either by stopping the backup thread from issuing Commit requests or by causing the file manager to ignore Commit requests, e.g., from the backup thread. “Resume Backup”: allows the backup thread to resume sending Commit requests or allows the file manager to respond to Commit requests, e.g., from backup thread. “Open File”: an entry is made in the open File Table; “Close File”: the corresponding entry in the open-file table is deleted and an entry is made to the pending-change table. “Delete File” an entry is made to the pending change table indicating the named file is to be deleted. “Shutdown”: indicates a system shutdown; in that case, the files are synchronized, and the file manager and the backup thread exit.

Open-file requests and entries in the open-file table specify: 1) a process identifier (ID) for the management process or client requesting an opening to write; 2) the file descriptor; and 3) the file name. File-close requests specify a process ID for the client and a file descriptor. The pending-change table specifies the file name, which can be obtained by looking up the process ID and file descriptor in the open-file table. Also, for each volatile file represented in the pending-change table, an indication is given to whether the file is to be modified (if the file was closed) or deleted (in response to a delete file request).

Herein, a “system” is a set of interacting non-transitory tangible elements, wherein the elements can be, by way of example and not of limitation, mechanical components, electrical elements, atoms, physical encodings of instructions, and process segments. Herein, “process” refers to a sequence of actions resulting in or involving a physical transformation.

Herein, “computer” refers to a hardware machine for physically encoded data in accordance with physically encoded instructions. Depending on context, reference to a computer may or may not include software installed on the computer. Herein, “device” refers to hardware. Herein, unless otherwise apparent from context, a functionally defined component (e.g., file manager) of a computer is a combination of hardware and software executing on that hardware to provide the defined functionality.

Herein, a “mission subsystem” is a computer-within-a-computer that executes user applications. Herein, a “management subsystem” is a computer-within-a-computer for managing the mission subsystem. In other words, a computer can host separate hardware computers: the mission subsystem which performs tasks relatively directly related to a user's purpose, while the management subsystem is devoted to managing and maintaining the mission subsystem. Each “subsystem” has its own processor, communications devices, storage media, and power supply. Herein, a “field-replaceable unit”, is a module of the mission subsystem that can be replaced without moving the host computer. The “health” of a field-replaceable unit refers to its current and projected ability to perform the task it is intended to perform.

Herein, “processor” refers to hardware for executing instructions. A processor can be a monolithic device, e.g., integrated circuit, a portion of a device, e.g., core of a multi-core integrated circuit, or a distributed or collocated set of devices. Herein, “communications devices” refers to hardware devices used for communication, including both network devices and devices used for input and output, e.g., human interface devices.

Herein, “storage medium” and “storage media” refer to a system including non-transitory tangible material in or on which information is or can be encoded with information including data and instructions. Persistent memory and volatile memory are types of storage media. “Persistent memory” refers to memory for which the contents are not lost when power is shut off; examples of persistent memory include most disk-based memories, and solid-state memories such as flash memory, read-only memories, but excluding most random-access memories (RAM), which are volatile memories. Herein, “persistent” files, file directories, and file systems, are stored in persistent memory, while “volatile” files, file directories, and file system are files stored in volatile memory.

“Firmware” refers to code in solid-state persistent memory, although, in some contexts it may refer to code in volatile memory resulting from booting code in solid-state persistent memory. For example, depending on context, file manager 334, which is created by booting boot code 318, may be considered firmware.

Herein, “main memory” refers to volatile memory, typically RAM, addressed and accessed by a hardware processor “directly”, as opposed to via a processor's input/output channels. Herein, “RAM drive” refers to volatile random-access memory configured to operate as a disk drive, i.e., via a processor's input/output channels. A “hardware RAM drive” uses hardware separate from main memory to operate as a solid-state disk drive. A “virtual RAM drive” refers to a block of volatile RAM configurable as part of main memory, but configured in software to operate as a disk drive.

Herein, “synchronizing” and its various forms refer to a process of reconciling differences between copies of an item. For example, synchronizing a persistent file system to a volatile file system means modifying the persistent file system as necessary so that the information it represents is the same as the information represented by the volatile file system. Herein, a “synchronization record” is a record that can be used to identify items to be reconciled in a synchronization process. Herein, “making an entry” can refer to making a new entry or overwriting an existing entry.

Herein, “redirect” means “directing to a location other than an intended or specified location”. Herein, a client process may issue a request for read or write access to a file in persistent memory. The file manager may direct the request to the file in persistent memory so that the request is fulfilled from persistent memory, or the file manager may redirect the request to the copy of the file in volatile memory so that the request is fulfilled from volatile memory.

In this specification, related art is discussed for expository purposes. Related art labeled “prior art”, if any, is admitted prior art. Related art not labeled “prior art” is not admitted prior art. The illustrated and other described examples, as well as modifications thereto and variations thereupon are within the scope of the following claims.

What is claimed is:

1. A computer-implemented process comprising:
copying persistent files from persistent memory to volatile memory to yield volatile files;
redirecting at least some requests to open to writing or to close to writing persistent files to the corresponding volatile files;
tracking openings to writing and closings to writing of volatile files to yield a synchronization record; and
synchronizing persistent files to volatile files based on the synchronization record.

2. A process as recited in claim 1 wherein the tracking includes:
in the event of an opening of a volatile file for writing, entering an identity of the file opened in an open-file table of the synchronization record;
in the event of a closing of a volatile file that has its identity entered in the open-file table, removing the identity of the closed file from the open-file table; and
in the event of a closing of a volatile file that does not have its identity entered in a pending-change table of the synchronization record, making a corresponding entry in the pending-change table.

3. A process as recited in claim 2 wherein the opening and closing are respectively in response to requests for access to the persistent file system from clients, at least some of the requests being fulfilled from the volatile file system once the copying is complete.

4. A process as recited in claim 3 wherein the file manager fulfills the requests for access to the persistent file system from persistent files prior to completion of the copying.

5. A process as recited in claim 3 wherein the file manager fulfills the requests for access to the persistent file system from persistent files if the persistent files have yet to be copied to the volatile file system.

6. A process as recited in claim 3 further comprising, in response to a request for deletion of a persistent file that has been copied to volatile memory to yield a corresponding volatile file, deleting the volatile file, updating the pending-change table to indicate that the persistent file is to be deleted, the synchronizing including deleting persistent files corresponding to volatile files indicated to be deleted in the pending-change table.

7. A process as recited in claim 3 further comprising creating a virtual RAM drive in the volatile memory, the copying including copying files to the virtual RAM drive.

8. A system comprising non-transitory persistent storage media encoded with code that, when executed by a processor, creates a file manager to:
copy persistent files of a persistent file system in persistent memory to a volatile file system in volatile memory to yield volatile files;
redirect at least some requests for opening and closing to writing said persistent files to respective ones of said volatile files;
track the openings and closings of the volatile files so as to update a synchronization record; and
synchronize the persistent files to the volatile files based on the synchronization record.

9. A system as recited in claim 8 further comprising the processor, the processor executing clients that send messages to the file manager that performs the copying, directing, tracking, and synchronizing.

10. A system as recited in claim 9 further wherein the boot code is further to create a virtual RAM drive in the volatile memory, the copying including copying the files to the virtual RAM drive.

11. A system as recited in claim 9 wherein the tracking includes tracking the openings by entering an identity of an opened volatile file in an open-file table of the synchronization record.

12. A system as recited in claim 11 where the tracking further includes tracking the closings in part by removing an identity of a closed file from the open-file table.

13. A system as recited in claim 11 wherein the tracking the closings further includes making corresponding entries in a pending-change table of the synchronization record, the synchronizing being based on the pending-change table.

14. A system as recited in claim 13 wherein the tracking further includes, in response to a request calling for deletion of a persistent file that has been copied to volatile memory to yield a corresponding volatile file, deleting the volatile file, and updating the pending-change table to indicate that the persistent file is to be deleted, the synchronizing including deleting persistent files indicated to be deleted in the pending-change table.

15. A system as recited in claim 9 wherein the directing includes directing requests to persistent files until all of the persistent files have been copied to yield respective volatile files.

16. A computer system comprising:
a mission subsystem to execute application software, the mission subsystem including hardware in the form of field-replacement units, and
a management subsystem including a processor, communications devices to communicate with a management station over an out-of-band network, and storage media including volatile memory and persistent memory, the persistent memory being encoded with
persistent files of health repository code data regarding the field-replaceable units, and
boot code to, when executed by the processor, cause the persistent files to be copied to the volatile memory to yield volatile files.

17. A computer system as recited in claim 16 wherein the boot code is further executable to create a file manager for redirecting at least some requests to open for writing or to close to writing persistent files to the corresponding volatile files.

18. A computer system as recited in claim 17 wherein the boot code is further executable to track openings to writing and closings to writing of volatile files to yield a synchronization record.

19. A computer system as recited in claim 18 wherein the code is further executable to synchronize persistent files to volatile files based on the synchronization record.

20. A computer system as recited in claim 19 wherein the tracking includes:
in the event of an opening of a volatile file for writing, entering an identity of the file opened in an open-file table of the synchronization record;
in the event of a closing of a volatile file that has its identity entered in the open-file table, removing the identity of the closed file from the open-file table; and
in the event of a closing of a volatile file that does not have its identity entered in a pending-change table of the synchronization record, making a corresponding entry in the pending-change table.
